(19) United States
(12) Patent Application Publication
(10) Pub. No.: US 2012/0208308 A1
(43) Pub. Date: Aug. 16, 2012

(54) METHOD MANUFACTURING SEMICONDUCTOR LIGHT EMITTING DEVICE

(75) Inventor: Takeyuki SUZUKI, Kanagawa-ken (JP)

(73) Assignee: Kabushiki Kaisha Toshiba, Tokyo (JP)

(21) Appl. No.: 13/209,142

(22) Filed: Aug. 12, 2011

(30) Foreign Application Priority Data
Feb. 10, 2011 (JP) 2011-27644

(51) Int. Cl. H01L 33/02

(52) U.S. Cl. 438/29; 257/E33.023

(57) ABSTRACT

According to one embodiment, a method is disclosed for manufacturing a semiconductor light emitting device having a stacked body of nitride semiconductor including a light emitting layer. The method can include selectively etching a substrate in an atmosphere containing chlorine and nitrogen, using a carbon-containing mask formed on a surface of the substrate translucent to light emission emitted from the light emitting layer. The method can include forming a nitride semiconductor layer on the etched surface of the substrate, the nitride semiconductor having a higher refractive index than the substrate. In addition, the method can include forming the stacked body including the nitride semiconductor layer on the substrate.

### CROSS-REFERENCE TO RELATED APPLICATIONS

This application is based upon and claims the benefit of priority from the prior Japanese Patent Application No. 2011-27644, filed on Feb. 10, 2011; the entire contents of which are incorporated herein by reference.

### FIELD

Embodiments described herein relate generally to a method for manufacturing a semiconductor light emitting device.

### BACKGROUND

A GaN-based nitride semiconductor is provided on e.g. a sapphire substrate with unevenness formed on the surface. This can improve the efficiency of extracting light from the nitride semiconductor and increase optical output from a blue LED. However, the light extraction efficiency depends on the shape of the unevenness provided on the substrate, and leaves room for improvement by its optimization. Thus, there is a need for a method for manufacturing a semiconductor light emitting device capable of improving the shape of the unevenness provided on the substrate to increase optical output.

### BRIEF DESCRIPTION OF THE DRAWINGS

FIGS. 1A to 1C are schematic views illustrating a semiconductor light emitting device according to an embodiment;

FIGS. 2A and 2B are views showing a shape of the unevenness provided on the sapphire substrate and the relationship between the shape and a light extraction efficiency;

FIGS. 3A to 3C are cross-sectional views schematically showing a manufacturing process of the light emitting device according to the embodiment;

FIGS. 4A and 4B are schematic views showing the manufacturing process following FIG. 3C;

FIG. 5 is a schematic view showing an etching apparatus according to the embodiment;

FIGS. 6A to 6D are cross-sectional SEM images showing the relationship between the shape of the unevenness provided on the sapphire substrate and the etching condition;

FIG. 7 is a graph showing the relationship between the etching condition and the etching rate of the sapphire substrate and the resist mask;

FIGS. 8A and 8B are plan views schematically showing a wafer holder of an etching apparatus according to a variation of the embodiment; and

FIGS. 9A and 9B are schematic views illustrating the wafer holder set on the lower electrode.

### DETAILED DESCRIPTION

In general, according to one embodiment, a method is disclosed for manufacturing a semiconductor light emitting device having a stacked body of nitride semiconductor including a light emitting layer. The method can include selectively etching a substrate in an atmosphere containing chlorine and nitrogen, using a carbon-containing mask formed on a surface of the substrate being translucent to light emission emitted from the light emitting layer. The method can include forming a nitride semiconductor layer on the etched surface of the substrate, the nitride semiconductor layer having a higher refractive index than the substrate. In addition, the method can include forming the stacked body including the nitride semiconductor layer on the substrate.

Various embodiments will be described hereinafter with reference to the accompanying drawings. In the following embodiments, like portions in the drawings are labeled with like reference numerals, and the detailed description thereof is omitted as appropriate. The different portions are described as appropriate.

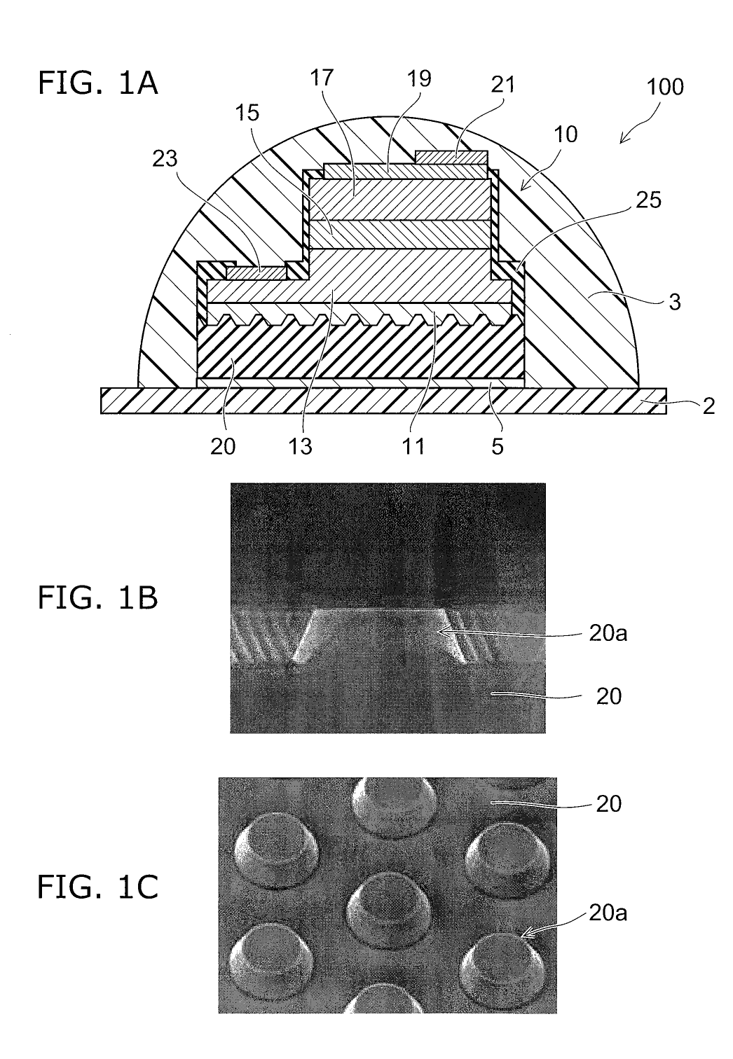

FIGS. 1A to 1C are schematic views illustrating a semiconductor light emitting device 100 according to an embodiment. FIG. 1A is a schematic view showing the cross-sectional structure of the semiconductor light emitting device 100. FIG. 1B shows a protrusion provided on the surface of a sapphire substrate. FIG. 1C shows the surface of the sapphire substrate provided with protrusions.

The semiconductor light emitting device 100 is a so-called white LED made of nitride semiconductor. As shown in FIGS. 1A to 1C, for instance, an LED chip 10 is bonded onto a base 2 of a package. The LED chip 10 is covered with a transparent resin 3.

For instance, the LED chip 10 is bonded with a transparent resin 5 onto the base 2 made of a white resin reflecting light emission of the LED chip 10. Alternatively, a reflective metal electrode may be formed on the back surface of the LED chip 10, and the LED chip 10 may be bonded with a solder material.

The transparent resin 3 has a lower refractive index than the LED chip 10, and has the property of externally extracting light emission in the LED chip 10. The transparent resin 3 also functions as a sealant for the LED chip 10 and a metal wire (not shown) connected to the electrode of the LED chip 10.

The LED chip 10 includes e.g. a stacked body in which a gallium nitride (GaN) buffer layer 11, an n-type GaN layer 13, a light emitting layer 15, and a p-type GaN layer are sequentially stacked. These nitride semiconductor layers are provided on a sapphire substrate 20 translucent to light emission. The sapphire substrate 20 can be replaced by e.g. GaN and SiC.

On the p-type GaN layer 17, a transparent electrode 19 transmitting light emission emitted from the light emitting layer 15, and a p-electrode 21 are provided. Furthermore, the p-type GaN layer 17 and the light emitting layer 15 are selectively etched, and an n-electrode 23 is provided on the surface of the exposed n-type GaN layer.

Metal wires, not shown, are bonded to the p-electrode 21 and the n-electrode 23, and connected to current supply terminals of the package. Holes are supplied from the p-electrode, and electrons are supplied from the n-electrode. Thus, electrons and holes are recombined in the light emitting layer 15 and emit light. The light emitting layer 15 includes e.g. a quantum well formed from an InGaN well layer and a GaN barrier layer, and emits blue light emission.

The light emission emitted from the light emitting layer is transmitted through the transparent electrode 19, propagated upward, and emitted to the outside of the LED chip 10. The light emission also includes a component propagated laterally, transmitted through a protective film 25 provided on the side surface of the LED chip, and emitted outside.

On the other hand, the refractive index of the stacked body including the GaN buffer layer 11, the n-type GaN layer 13, and the p-type GaN layer 17 is higher than the refractive index of the sapphire substrate 20 and the transparent resin 3 covering the LED chip 10. Hence, light emission emitted from the light emitting layer 15 is attenuated by repeated reflection inside the stacked body and includes components not emitted outside.

Thus, unevenness is provided between the sapphire substrate 20 and the GaN buffer layer 11 having a higher refractive index than the sapphire substrate 20. Light emission emitted from the light emitting layer 15 is scattered at the interface of the unevenness to change its propagation direction. Furthermore, reflection of light directed from the GaN buffer layer 11 to the sapphire substrate 20 is reduced. Thus, the light propagated in the sapphire substrate 20 and reflected at the interface between the sapphire substrate 20 and the base 2 is extracted outside. This can suppress multiple reflection of light inside the stacked body, and increase the extraction efficiency of light emission emitted from the light emitting layer 15.

FIG. 1B is a SEM (scanning electron microscope) image showing a cross section of a protrusion 20a provided on the surface of the sapphire substrate 20. On the other hand, FIG. 1C is a SEM image of a sapphire substrate provided with protrusions 20a taken from obliquely above.

As shown in FIGS. 1A and 1B, unevenness made of a plurality of protrusions 20a can be formed on the surface of the sapphire substrate 20. Furthermore, as shown in FIG. 1A, the protrusion 20a can be formed with a sloped side surface.

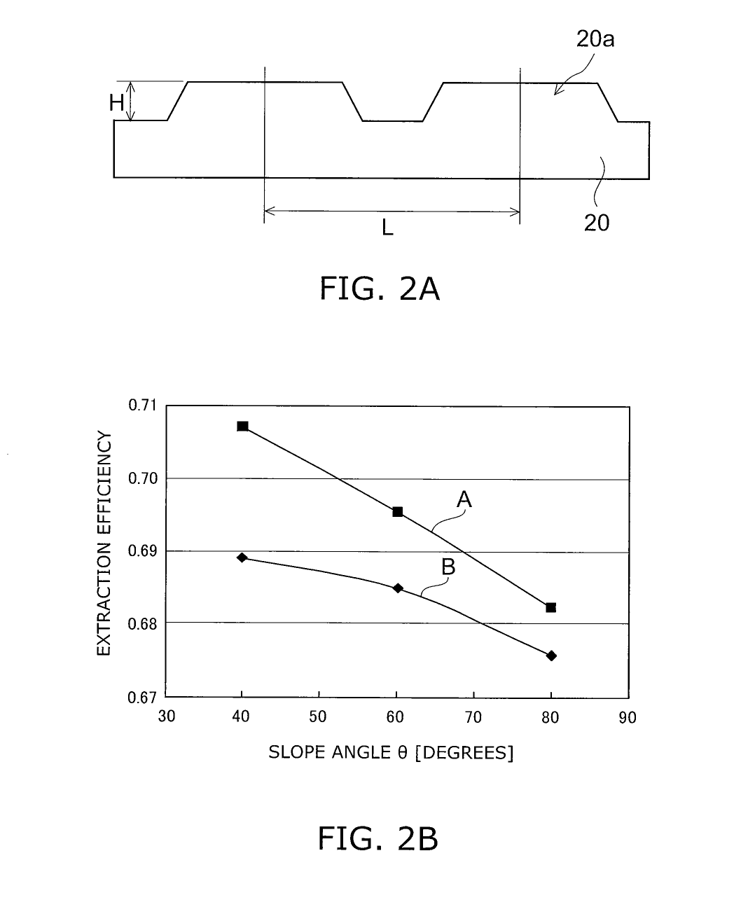

FIG. 2A is a schematic view showing a cross section of the protrusion 20a. Parameters quantifying its shape such as thickness H, pitch L, and slope angle θ of the side surface are shown.

The light extraction efficiency can be increased by optimizing each of the thickness H, pitch L, and slope angle θ. For instance, the thickness H of the protrusion 20a can be controlled by the etching time of the sapphire substrate. The pitch L can be controlled by photolithography. Hence, the thickness H and the pitch L have been easily optimized. In contrast, the slope angle θ of the side surface is not controlled sufficiently, and leaves room for improvement.

FIG. 2B is a graph showing a simulation result of the relationship between the slope angle θ of the side surface of the protrusion 20a and the light extraction efficiency. The horizontal axis represents the slope angle θ, and the vertical axis represents the light extraction efficiency. Graph A shown in this figure shows the variation of light extraction efficiency in the case where the height H of the protrusion 20a is 1.5 μm, and the pitch L is 5 μm. On the other hand, graph B shows the variation of light extraction efficiency in the case where the height H is 0.5 μm, and the pitch L is 5 μm.

Both the graphs A and B indicate that the light extraction efficiency decreases with the increase of the slope angle θ. Furthermore, it is found that the light extraction efficiency is higher in A, in which the protrusion 20a is higher.

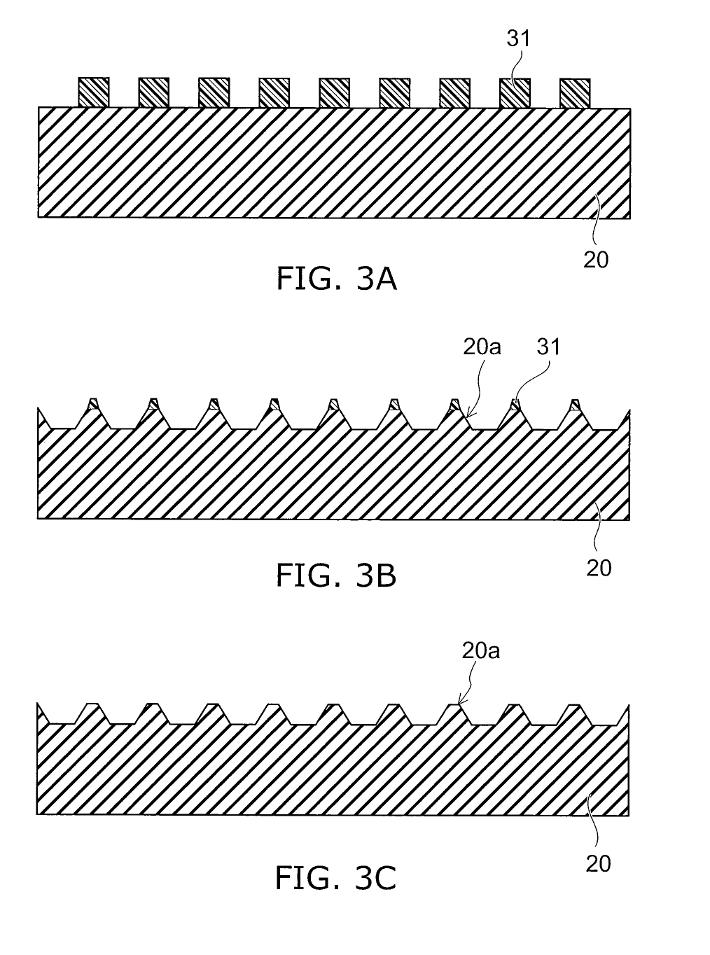

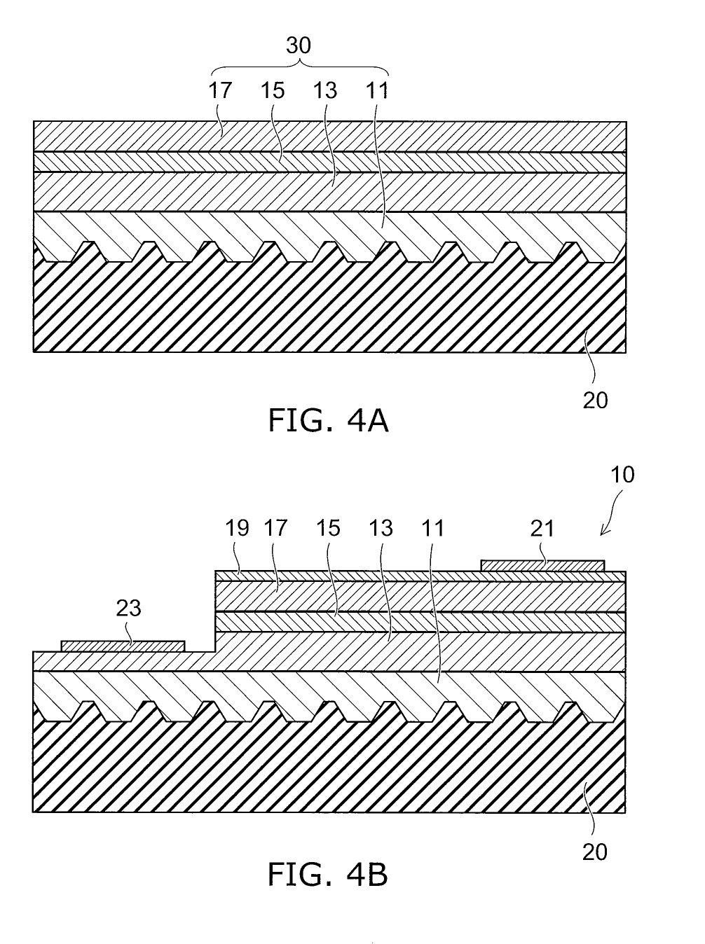

Next, with reference to FIGS. 3A to 4B, a process for manufacturing the semiconductor light emitting device 100 according to the embodiment is described. FIGS. 3A to 4B are schematic views showing a cross section of a wafer in respective manufacturing processes.

First, as shown in FIG. 3A, an etching mask 31 for forming protrusions 20a is formed on the surface of a sapphire substrate 20. The etching mask 31 can be made of e.g. a resist film.

Subsequently, as shown in FIG. 3B, the sapphire substrate 20 is etched to form protrusions 20a. For instance, an RIE (reactive ion etching) apparatus using an etching gas containing chlorine (Cl₂) and nitrogen (N₂) can be used.

When the sapphire substrate 20 is etched, the etching mask 31 is etched simultaneously. Hence, the protrusion 20a is shaped with a sloped side surface. After the etching of the sapphire substrate is completed, for instance, the resist mask (etching mask 31) is removed with a mixed solution of sulfuric acid and hydrogen peroxide water. Thus, as shown in FIG. 3C, protrusions 20a can be formed on the sapphire substrate.

Next, as shown in FIG. 4A, on the surface of the etched sapphire substrate 20, a GaN buffer layer 11, an n-type GaN layer 13, a light emitting layer 15, and a p-type GaN layer are sequentially formed. The stacked body 30 including these nitride semiconductors can be formed using e.g. the MOCVD (metal organic chemical vapor deposition) method.

Subsequently, as shown in FIG. 4B, a transparent electrode 19 is formed on the surface of the p-type GaN layer 17. The transparent electrode 19 can be made of e.g. an ITO (indium tin oxide) film. Then, a p-electrode 21 is formed on the transparent electrode 19. The p-electrode 21 can be made of e.g. a metal film in which titanium (Ti) and gold (Au) are sequentially stacked.

Furthermore, the p-type GaN layer 17 and the light emitting layer 15 are selectively etched to expose the surface of the n-type GaN layer 13. The etching of the p-type GaN layer 17 and the light emitting layer 15 can be performed by e.g. the RIE method. Then, an n-electrode 23 is formed on the surface of the n-type GaN layer 13. The n-electrode 23 can be made of e.g. a metal film in which Ti and aluminum (Al) are sequentially stacked.

Next, a protective film 25 covering the side surface of the GaN buffer layer 11, the n-type GaN layer 13, the light emitting layer 15, and the p-type GaN layer 17 is formed. Thus, an LED chip 10 is completed (see FIG. 1A). The protective film 25 can be made of e.g. a silicon dioxide (SiO₂) film. Subsequently, the sapphire substrate 20 is cut and separated into individual LED chips 10. Then, the LED chip 10 is bonded onto a package, and further molded with a transparent resin 3. Thus, a semiconductor light emitting device 100 is completed.

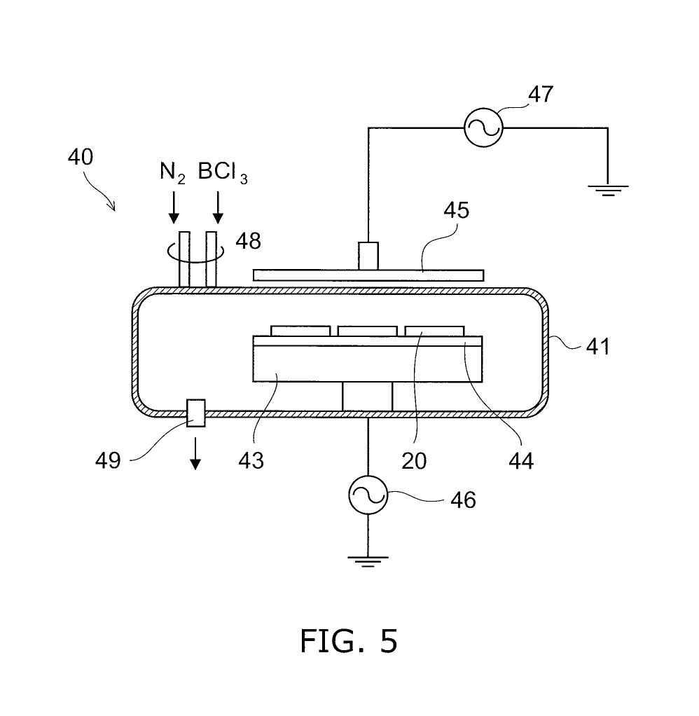

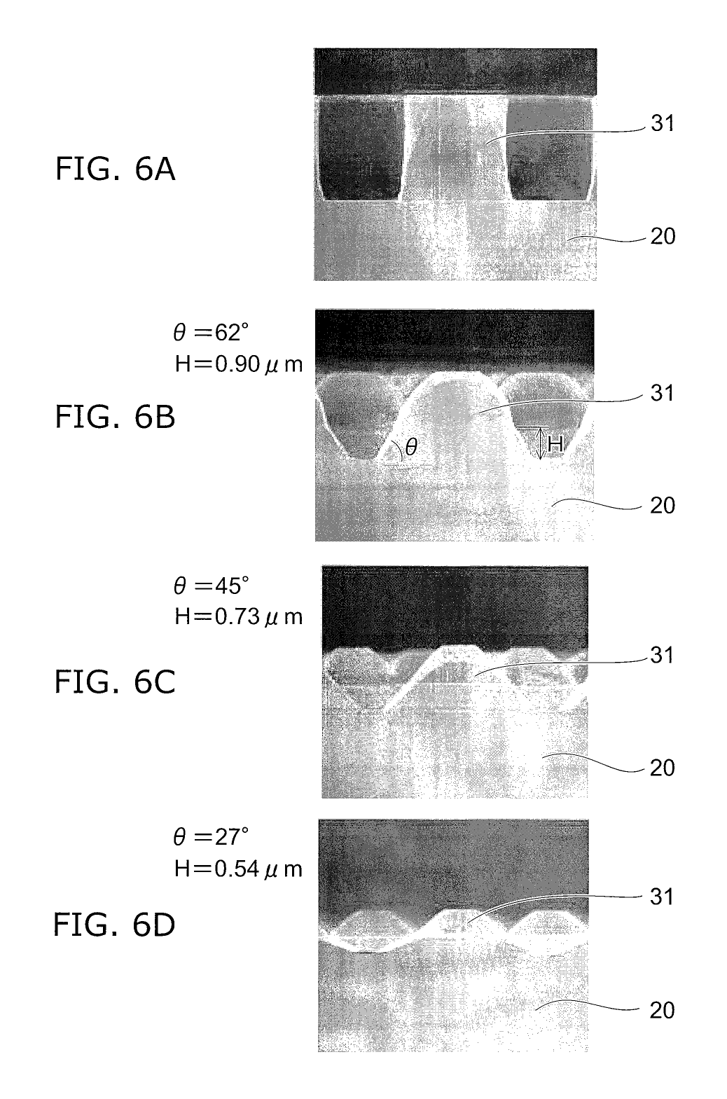

Next, with reference to FIGS. 5 to 6D, a method for forming the unevenness of the sapphire substrate 20 is described in detail.

FIG. 5 is a schematic view showing an etching apparatus 40. To etch the sapphire substrate 20, for instance, a dry etching apparatus of the ICP (inductive coupling plasma) type can be used.

In the etching apparatus 40, a lower electrode 43 is provided inside a reaction chamber 41. A wafer holder 44 is set on the lower electrode 43. A sapphire substrate 20 to be etched is mounted on the surface of the wafer holder 44. The inside of the reaction chamber 41 is pressure reduced by a vacuum pump, not shown. From a gas piping 48, for instance, an etching gas containing boron trichloride (BCl₃) and N₂ is supplied into the reaction chamber 41. Thus, the inside of the reaction chamber 41 is replaced by an etching gas atmosphere. Furthermore, the etching gas is exhausted from an exhaust port 49 by the vacuum pump. Thus, the inside of the reaction chamber 41 is maintained at a constant pressure. Here, instead of N₂, for instance, ammonia gas (NH₃) and nitrous oxide gas (N₂O) may be used.

Subsequently, radio frequency power is supplied from a radio frequency power supply 47 to an antenna electrode 45 opposed to the lower electrode 43 to generate plasma between the lower electrode 43 and the antenna electrode 45. Then, active chlorine radicals are generated from the etching gas decomposed in the plasma and etch the sapphire substrate. Here, radio frequency power is applied from a bias power supply 46 connected to the lower electrode 43 to bias the lower electrode 43. This can attract ions in the plasma and facilitate etching the sapphire substrate 20.

FIGS. 6A to 6D are cross-sectional SEM images showing the relationship between the shape of the unevenness provided on the sapphire substrate and the dry etching condition. FIG. 6A shows a cross section of the resist mask (etching mask) 31 formed on the sapphire substrate 20. FIGS. 6B to 6D show cross sections of dry etched sapphire substrates 20 for different supply amounts of N₂.

The dry etching was performed under the following condition, for instance. The pressure inside the reaction chamber 41 was 1.0 Pa. The radio frequency power supplied to the antenna electrode 45 was 750 W. The radio frequency power biasing the lower electrode 43 was 150 W. The temperature of the lower electrode 43 was 15° C.

In the processing of the sample shown in FIG. 6B, the sample was etched only with BCl₃ without supplying N₂. As shown in this figure, the slope angle θ of the side surface of the protrusion 20a formed on the sapphire substrate 20 is 62°. Furthermore, it is found that the resist mask 31 left on the protrusion 20a is also etched and deformed into a dome shape.

In the processing of the sample shown in FIG. 6C, N₂ was added to the etching gas. The flow rate ratio of BCl₃ to N₂ was set to 87.5:12.5. As shown in this figure, the slope angle θ of the side surface of the protrusion 20a is 45°, which is smaller than that of the sample shown in FIG. 6B. Furthermore, the height H of the protrusion 20a is lower than that of the sample of FIG. 6B. Thus, it is found that the etching rate of the sapphire substrate is slower.

On the other hand, the resist mask 31 is etched in a trapezoidal shape, and etching is more advanced than in the sample of FIG. 6B. That is, by adding N₂ to the etching gas, the etching rate of the resist mask 31 can be made relatively faster, and the slope angle θ of the side surface can be made smaller.

In the processing of the sample shown in FIG. 6D, the supply amount of N₂ was further increased so that the flow rate ratio of BCl₃ to N₂ was set to 75:25. As a result, the slope angle θ of the side surface is 27°, and the height H of the protrusion 20a is even lower. The etching of the resist mask 31 is even more advanced.

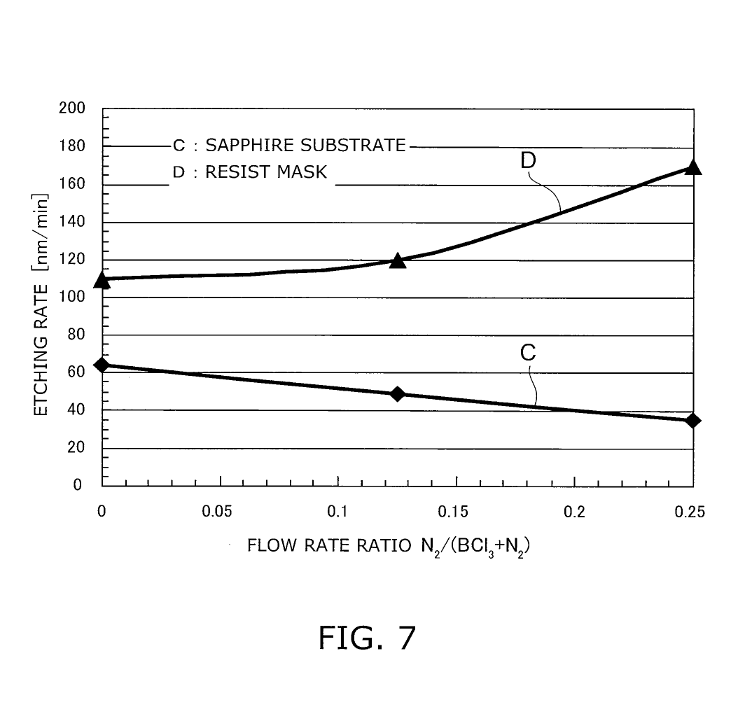

FIG. 7 is a graph showing the N₂ ratio in BCl₃/N₂ mixed gas and the etching rate of the sapphire substrate and the resist mask. It is found that as the N₂ flow rate increases, the etching rate of the sapphire substrate becomes slower, and the etching rate of the resist mask becomes faster.

For instance, in the processing without addition of N₂ shown in FIG. 6B, the slope angle θ of the side surface of the protrusion 20a cannot be made smaller than 60° even if the other etching conditions are changed. That is, as shown in the embodiment, addition of nitrogen to the chlorine-containing etching gas suppresses the etching rate of the sapphire substrate, and advances the etching of the resist mask 31. Thus, the slope angle θ of the side surface of the protrusion 20a can be made smaller. This can increase the light extraction efficiency as shown in FIG. 2B.

As described above, addition of nitrogen to the etching gas suppresses the etching rate of the sapphire substrate, and advances the etching of the resist mask 31. The cause of this is considered as follows. For instance, AlN and BN are produced during the reaction, and reattachment of them decreases the etching rate of the sapphire substrate 20. Furthermore, by addition of nitrogen, active species etching the carbon-containing resist are increased in the plasma. This advances the etching of the resist mask 31. Hence, the etching mask is not limited to a resist film, but other carbon-containing materials such as a film containing organic matter can be used.

Furthermore, the supply source of nitrogen is not limited to gases containing nitrogen atoms as long as it supplies nitrogen radicals in the plasma induced between the antenna electrode 45 and the lower electrode 43.

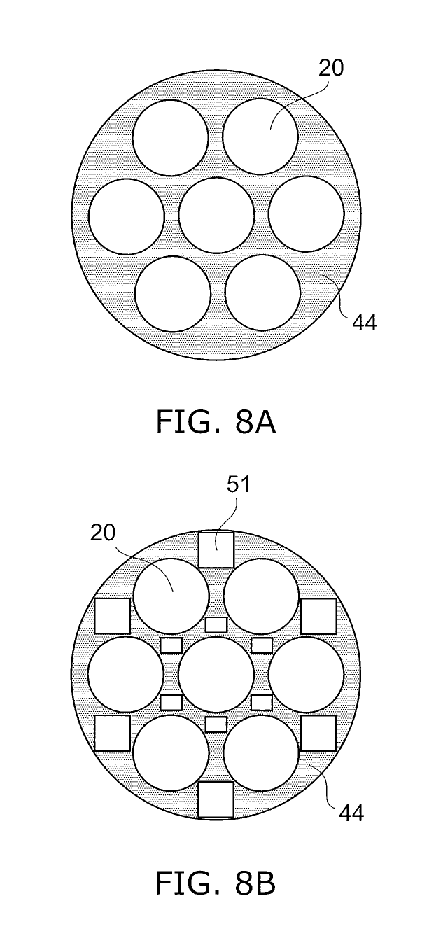

For instance, FIGS. 8A and 8B are plan views schematically showing the wafer holder 44 of a dry etching apparatus according to a variation of the embodiment. As shown in FIG. 8A, for instance, the wafer holder 44 is provided like a plate, and sapphire substrates 20 are mounted on the surface of the wafer holder 44. The wafer holder 44 can include e.g. nitrides such as boron nitride (BN) or silicon nitride (SiN). Then, nitrogen can be sputtered by high energy ions in the plasma to generate nitrogen radicals.

Alternatively, as shown in FIG. 8B, nitrides may be placed between the sapphire substrates 20 mounted on the wafer holder 44. For instance, small pieces made of at least one nitride of GaN, BN, SiN, and TiN can be mounted on the wafer holder 44.

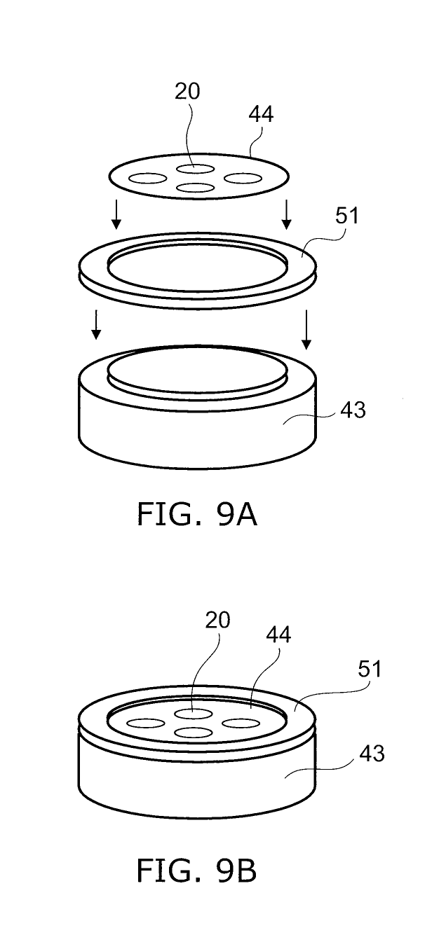

FIG. 9A is an exploded view schematically showing the procedure for setting the wafer holder 44 on the lower electrode 43. FIG. 9B is a schematic view illustrating the wafer holder 44 set on the lower electrode 43.

As shown in FIG. 9A, for instance, a focus ring 51 is attached along the outer edge of the lower electrode 43. Subsequently, the wafer holder 44 is set inside the focus ring 51. Then, as shown in FIG. 9B, with the lower electrode 43 covered with the wafer holder 44 and the focus ring 51, the sapphire substrate 20 mounted on the wafer holder 44 is etched.

The focus ring 51 is placed along the outer periphery of the wafer holder. The focus ring 51 protects the lower electrode 43 against exposure to plasma. Thus, by causing this focus ring 51 to contain nitrogen, nitrogen radicals can be emitted.

More specifically, at least one of the wafer holder 44 and the focus ring is caused to contain nitrogen. Thus, nitrogen radicals can be supplied into the plasma. This suppresses the etching rate of the sapphire substrate, and advances the etching of the resist mask 31.

The wafer holder 44 can be caused to contain nitrogen by the aforementioned methods. The focus ring 51 is made of a material including at least one of e.g. GaN, AlN, and SiN. Alternatively, the focus ring 51 may be made of a sintered body of a mixture of alumina (Al₂O₃) and AlN.

In the example described in the above embodiment, by providing protrusions 20a, unevenness is formed on the surface of the sapphire substrate 20. However, the embodiment is not limited thereto. For instance, depressions can be provided on the surface of the sapphire substrate 20. The slope of the sidewall of the depression can be controlled to increase the light extraction efficiency.

The “nitride semiconductor” referred to herein includes group III-V compound semiconductors of BₓIn_{y}Al_{z}Ga_{1-x-y-z}N (0≦x≦1, 0≦y≦1, 0≦z≦1, 0≦x+y+<1), and also includes mixed crystals containing phosphorus (P) or arsenic (As) as a group V element besides N (nitrogen). Furthermore, the “nitride semiconductor” also includes those further containing various elements added for controlling various material properties such as conductivity type, and those further containing various unintended elements.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor light emitting device having a stacked body of nitride semiconductor including a light emitting layer, the method comprising:
selectively etching a substrate in an atmosphere containing chlorine and nitrogen, using a carbon-containing mask formed on a surface of the substrate being translucent to light emission emitted from the light emitting layer;
forming a nitride semiconductor layer on the etched surface of the substrate, the nitride semiconductor layer having a higher refractive index than the substrate; and
forming the stacked body including the nitride semiconductor layer on the substrate.

2. The method according to claim 1, wherein the chlorine is supplied from an etching gas containing boron trichloride (BCl₃).

3. The method according to claim 1, wherein the substrate is placed in a reaction chamber, and an etching gas containing the chlorine and the nitrogen is supplied into the reaction chamber.

4. The method according to claim 3, wherein the etching gas contains one of nitrogen gas, ammonia gas and nitrous oxide gas.

5. The method according to claim 1, wherein the substrate is mounted on a wafer holder, and the nitrogen is supplied from a nitride contained in the wafer holder.

6. The method according to claim 5, wherein the wafer holder contains one of boron nitride and silicon nitride.

7. The method according to claim 1, wherein the substrate is mounted on a wafer holder, and the nitrogen is supplied from a nitride placed on the wafer holder.

8. The method according to claim 7, wherein the nitride includes at least one of gallium nitride, boron nitride, silicon nitride, and titanium nitride.

9. The method according to claim 1, wherein the substrate is mounted on a wafer holder, a focus ring being placed along outer periphery of the wafer holder, and at least one of the wafer holder and the focus ring includes a nitride supplying the nitrogen.

10. The method according to claim 9, wherein the focus ring includes at least one of gallium nitride, aluminum nitride, and silicon nitride.

11. The method according to claim 9, wherein the focus ring includes alumina and aluminum nitride.

12. The method according to claim 1, wherein the mask is a resist film.

13. The method according to claim 1, wherein the substrate is etched by using an RIE method.

14. The method according to claim 13, wherein the substrate is mounted on a wafer holder, and a radio frequency bias is applied to an electrode on a side of the wafer holder.

15. The method according to claim 1, wherein a protrusion is formed on the surface of the substrate.

16. The method according to claim 15, wherein the protrusion includes a side surface having slope angle of 60° or less.

17. The method according to claim 1, wherein a depression is formed on the surface of the substrate.

18. The method according to claim 1, wherein the substrate is a sapphire substrate.

19. The method according to claim 1, wherein the nitride semiconductor layer includes gallium nitride (GaN).

20. The method according to claim 1, wherein the stacked body includes gallium nitride (GaN).
